(19) United States
(12) Patent Application Publication
(10) Pub. No.: US 2016/0379854 A1
(43) Pub. Date: Dec. 29, 2016

(54) Vacuum Compatible LED Substrate Heater

(71) Applicant: Varian Semiconductor Equipment Associates, Inc., Gloucester, MA (US)

(72) Inventors: Robert Brent Vopat, Austin, TX (US); Gary E. Wyka, Austin, TX (US); David Blahnik, Round Rock, TX (US); Jason M. Schaller, Austin, TX (US); William T. Weaver, Austin, TX (US)

(21) Appl. No.: 14/753,991

(22) Filed: Jun. 29, 2015

(51) Int. Cl. H01L 21/67; H05B 3/00

(52) U.S. Cl. CPC H01L 21/67115; H05B 3/0047; H05B 3/009

(57) ABSTRACT

A system for heating substrates within a chamber, which may be maintained at vacuum conditions, is disclosed. The LED substrate heater comprises a base having a recessed portion surrounded by sidewalls. A plurality of light emitting diodes (LEDs) are disposed within the recessed portion. The LEDs may be GaN or GaP LEDs, which emit light at a wavelength which is readily absorbed by silicon or a coating on the silicon, thus efficiently and quickly heating the substrate. A transparent window is disposed over the recessed portion, forming a sealed enclosure in which the LEDs are disposed. A sealing gasket may be disposed between the sidewalls and the window.

### FIELD

Embodiments of the present disclosure relate to system for heating a substrate, and more particularly, for heating a substrate using LEDs, such as in a vacuum chamber.

### BACKGROUND

The fabrication of a semiconductor device involves a plurality of discrete and complex processes. The semiconductor substrate typically undergoes many processes during the fabrication process. These processes may occur in a processing chamber, which may be maintained at a different processing condition than the environment. For example, the processing chamber may be maintained at vacuum conditions.

Heating substrates before and/or after processing is common in many semiconductor fabrication processes. In many cases, the substrate is heated to a temperature close to the process temperature and then transported to the platen. This preheating may help prevent substrate warping, popping and movement when the cold substrate contacts the hot platen. These phenomenon may cause the creation of particles and mishandling, and may reduce overall process yield.

Additionally, in some embodiments, a substrate may be warmed after being subjected to a cold process to eliminate the possibility of condensation when the substrate exits the chamber.

In certain embodiments, a dedicated preheating station may be used to perform this function. The preheating station may comprise one or more infrared lamps that are focused on the substrate. While the preheating station is effective at raising the temperature of the substrate, the preheating station has a negative impact on throughput. Specifically, a substrate may be disposed at the preheating station for a significant amount of time in order for the substrate to reach the desired temperature. Additionally, the infrared lamps are fairly inefficient in heating the substrates. Further, the infrared lamps may be rather large and consume a significant amount of space within the chamber. For example, infrared lamps may be between 4 and 8 inches thick.

It would be beneficial if there were an apparatus to heat the substrates without the use of infrared lamps. Further, it would be advantageous if the apparatus occupied less space within the chamber.

### SUMMARY

A system for heating substrates within a chamber, which may be maintained at vacuum conditions, is disclosed. The LED substrate heater comprises a base having a recessed portion defined by sidewalls. A plurality of light emitting diodes (LEDs) are disposed within the recessed portion. The LEDs may be GaN or GaP LEDs, which emit light at a wavelength which is readily absorbed by silicon or a coating on the silicon, thus efficiently and quickly heating the substrate. A window is disposed over the recessed portion, forming a sealed enclosure in which the plurality of LEDs is disposed. A sealing gasket may be disposed between the sidewalls and the window.

According to one embodiment, an apparatus is disclosed. The apparatus comprises a sealed enclosure containing an electrical circuit comprising a plurality of LEDs, wherein a top surface of the sealed enclosure comprises a window that is transparent at a wavelength emitted by the plurality of LEDs. In certain embodiments, the sealed enclosure is filled with an encapsulate to remove air.

According to another embodiment, an LED substrate heater is disclosed. The LED substrate heater comprises a base having a recessed portion surrounded by sidewalls; an electrical circuit, comprising a plurality of LEDs, disposed in the recessed portion; and a window disposed on top of the sidewalls and covering the recessed portion, forming a sealed enclosure in which the electrical circuit is disposed, wherein the window is transparent at a wavelength emitted by the plurality of LEDs. In certain embodiments, the electrical circuit comprises a printed circuit board, and the printed circuit board is in thermal communication with an upper surface of the recessed portion. In certain embodiments, the electrical circuit comprises insulating traces and conductive traces, wherein the insulating traces are applied directly to an upper surface of the recessed portion, the conductive traces are applied on top of the insulating traces, and the conductive traces are in electrical communication with the plurality of LEDs.

According to another embodiment, an LED substrate heater is disclosed. The LED substrate heater comprises a base having a recessed portion surrounded by sidewalls; an electrical circuit, comprising a plurality of LEDs arranged as a pattern of concentric circles, disposed in the recessed portion; an encapsulate disposed in the recessed portion; and a window disposed on top of the sidewalls, covering the recessed portion and in contact with the encapsulate, forming a sealed enclosure in which the electrical circuit is disposed, wherein the window and the encapsulate are transparent at a wavelength emitted by the plurality of LEDs. In certain embodiments, the pattern comprises a plurality of bands, where all concentric circles disposed in a particular band have a same number of LEDs. In certain embodiments, there are five bands.

### BRIEF DESCRIPTION OF THE FIGURES

For a better understanding of the present disclosure, reference is made to the accompanying drawings, which are incorporated herein by reference and in which:

FIG. 1 is a perspective view of a substrate heating system according to one embodiment;

FIG. 2 is a side view of the substrate heating system of FIG. 1 according to one embodiment;

FIG. 3 is a perspective view of a substrate heating system according to another embodiment;

FIG. 4 is an expanded view of the recessed portion of the substrate heating system of FIG. 3;

FIG. 5 shows a representative pattern that may be used for the LEDs; and

FIG. 6 shows the LED substrate heater as used in a chamber.

### DETAILED DESCRIPTION

As described above, in many applications, it may be advantageous to preheat a substrate prior to that substrate being processed. Further, substrates are often processed within chambers, which are maintained at vacuum conditions.

The use of vacuum conditions presents many challenges to the design of a LED substrate heater. For example, the choice of materials that may be used to construct the LED substrate heater may be limited, as many materials may outgas, contaminating the chamber. Additionally, sealed enclosures disposed within the chamber may have a pressure differential between the interior of the enclosure and the chamber, which may put significant or unacceptable stress of the walls of that sealed enclosure. Additionally, excess heat generated by the LED substrate heater should be removed, which may be made more difficult due to the lack of air in the chamber.

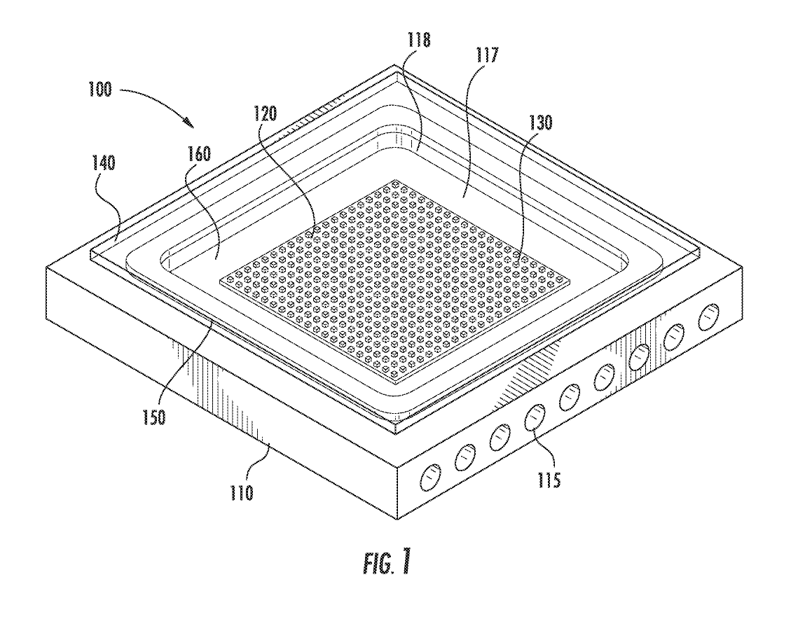

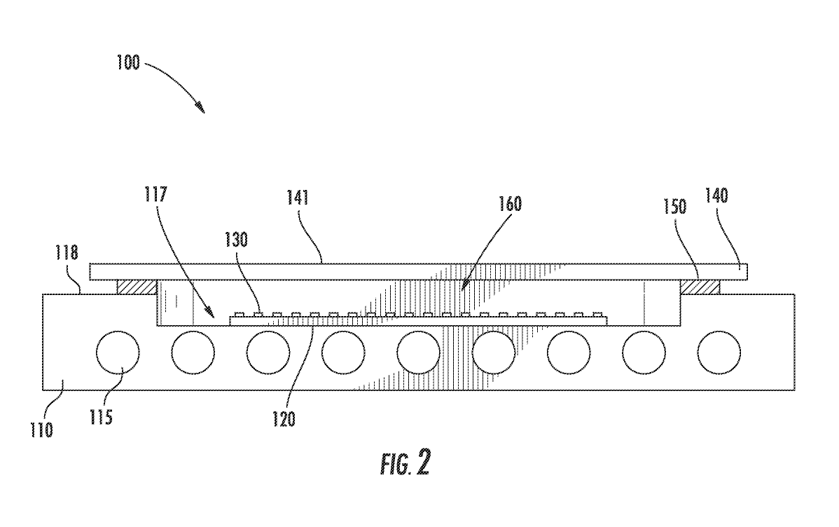

FIG. 1 shows a perspective view of a first embodiment of a LED substrate heater 100, which is compatible with vacuum conditions. FIG. 2 shows a cross-sectional view of the LED substrate heater 100 of FIG. 1.

The LED substrate heater 100 includes a base 110, which may be constructed of a thermally conductive material, such as aluminum, copper or other suitable materials. The base 110 may have a length and a width, which in certain embodiments, may be the same dimension. The example, the length and width of the base 110 may form a square, having a dimension greater than diameter of the substrate which the LED substrate heater 100 is configured to heat. For example, if the substrate is a silicon wafer having a diameter of 300 mm, the length and width of the base 110 may be large enough to accommodate an array of LEDs that is at least as large as the wafer. In other embodiments, the base 110 may be circular, having a diameter equal to or greater than that of the substrate that is disposed on it. For example, in one embodiment, the substrate may have a diameter of 300 mm, and the array of LEDs may have a diameter greater than 300 mm to insure uniform heating. For example, the array of LEDs 130 may have a diameter of 330 mm.

The base 110 may also have a height, orthogonal to the length and the width. The height of the base 110 may be less than 0.5 inches in certain embodiments. Disposed within the base 110 may be one or more conduits 115. These conduits 115 may extend through the length of the base 110, entering on one side and exiting on the opposite side of the base 110. In certain embodiments, the conduits 115 may be at least partially threaded, allowing a similarly threaded hose or tube to be inserted in the conduit 115 and affixed to the base 110. In operation, a fluid, such as water, another liquid or a gas, travels through the hose and passes through the conduits 115. This action allows the heat contained within the base 110 to be removed by the flowing fluid. Thus, conduits 115 serve as coolant channels. In other embodiments, the base 110 may be disposed on a thermal mass, which serves as a heat sink. In these embodiments, the conduits 115 may not be employed.

The top surface of the base 110 may have a recessed portion 117 that is surrounded by sidewalls 118. The recessed portion 117 may be sized so as to accommodate a printed circuit board 120. As noted above, the printed circuit board may be equal to, or slightly larger, than the substrate that is to be heated. The top surface of the recessed portion 117 may be polished to optimize its ability to reflect incident radiation from the substrate or the LEDs. While FIG. 1 shows a square base 110 having a square recessed portion 117, other embodiments are also possible. For example, the base 110 and the recessed portion 117 may both be circular. In another embodiment, one of the base 110 and the recessed portion 117 is square while the other is circular.

While FIG. 1 shows the base 110 as an integral component having a recess therein, other embodiments are also possible. For example, the base may have a flat top surface, and sidewalls, which are separate from the base, may be disposed around the perimeter of the base on its top surface. In this embodiment, the volume defined by the sidewalls and above the base is considered the recessed portion. Thus, the phrase “a base with a recessed portion” is not intended to be limited to only an integral component having a recess. Rather, it also includes other configurations that can be used to create a volume that can accommodate the LEDs and be sealed.

The printed circuit board 120 may include a plurality of high power LEDs 130, which emit light of a wavelength or a plurality of wavelengths that is readily absorbed by the substrates. For example, silicon exhibits high absorptivity and low transmissivity in the range of wavelengths between about 0.4 and 1.0 μm. Silicon absorbs more than 50% of the energy emitted in the range of wavelengths from 0.4 to 1.0 μm. LEDs that emit light in this range of wavelengths may be used. In certain embodiments, LEDs made from GaN are employed. These GaN LEDs emit light at a wavelength of about 450 nm. In certain embodiments, GaP LEDs are employed, which emit light at a wavelength between 610 and 760 nm.

The LEDs 130 may be varied in size. In certain embodiments, each LED may be 1.3 mm×1.7 mm. In another embodiment, each LED 130 may be 1 mm×1 mm. Of course, LEDs of other dimensions are also within the scope of the disclosure. The density of the LEDs 130 on the printed circuit board 120 may vary. For example, in one embodiment, a density of 8.65 LEDs/cm² may be used. In another embodiment, a density of 18.1 LEDs/cm² may be used. In other embodiments, densities of up to 78 LEDs/cm² may be used. As such, the density of the LEDs 130 is not limited by the disclosure.

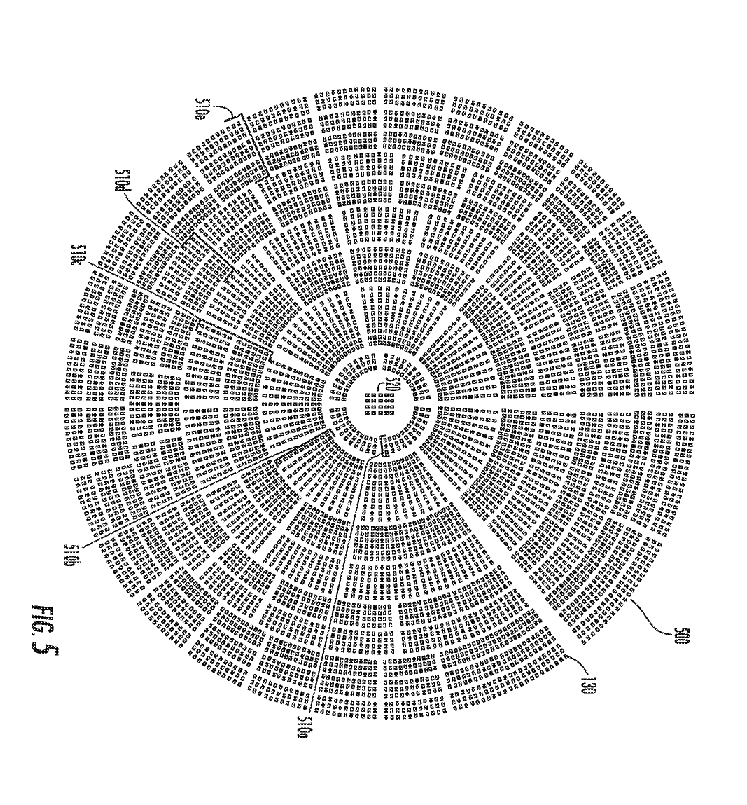

The LEDs 130 may be disposed as a regular array having a fixed number of rows and columns. In other embodiments, the LEDs 130 may be spaced in a non-uniform manner to optimize the heating of the substrate. In certain embodiments, the number of LEDs in each concentric circle may be related to the radius of that particular circle, such that outer concentric circles may have more LEDs than inner concentric circles. FIG. 5 shows a representative pattern of LEDs 130 that are arranged in concentric circles. In this embodiment, the concentric circles 500 are organized in bands 510a, 510b, 510c, 510d, 510e, where all of the circles in a particular band have the same number of LEDs 130. Of course, other configurations are also possible. Specifically, in outermost band 510e, which is furthest from the center of the pattern, each concentric circle 500 may have about 308 LEDs. There may be about 9 concentric circles 500 in outermost band 510e. In contrast, in innermost band 510a, which is closest to the center, the concentric circles 500 may each have only 44 LEDs. There may be about 3 concentric circles 500 in the innermost band 510a. The concentric circles 500 in bands 510b, 510c and 510d, which are located between innermost band 510a and outermost band 510e, may have 77, 154 and 231 LEDs, respectively. There may be 10 concentric circles in band 510b, twelve concentric circles 500 in band 510c and eight concentric circles 500 in band 510d. Inside of the innermost band 510a, there may be a small rectangular array 520 of LEDs, which are organized as rows and columns, such as 5 rows and 5 columns. Of course, the pattern of LEDs may include a different number of bands, which may have any number of LEDs. Further, the number of concentric circles 500 in each band may be different from that described above. Therefore, the configuration of LEDs 130 is not limited by this disclosure.

Referring to FIGS. 1 and 2, the LEDs 130 are electrically connected to a power source (not shown) through the printed circuit board 120. In certain embodiments, the printed circuit board 120 may be a metal core printed circuit board. Metal core printed circuit boards utilize a metal base layer, which may help conduct heat away from the LEDs 130 disposed on the printed circuit board 120. In certain embodiments, the printed circuit board 120 is thermally bonded to the top surface on the recessed portion 117 through the use of a thermal bonding agent (not shown). In other embodiments, the printed circuit board 120 may be physically attached to the base 110, such as by screws or more fastening means (not shown). The fastening means may insure physical contact between the underside of the printed circuit board 120 and the top surface of the recessed portion 117 to insure thermal conduction.

As shown in FIG. 1, a window 140 may be disposed on the top of the sidewalls 118. The window 140 may comprise quartz, borosilicate glass, or any other material that is transparent at the wavelengths emitted by the LEDs 130. The window 140 may be sized to extend beyond the recessed portion 117 and rest on the sidewalls 118. The window 140 may have a thickness of a few millimeters or more.

In certain embodiments, the window 140 may be affixed to the top of the sidewalls 118 using mechanical fasteners, such as brackets.

In embodiments where the LED substrate heater 100 is to be used in vacuum conditions, an encapsulate 160 may be used to fill the volume of the recessed portion 117. Thus, after the printed circuit board 120 has been installed, the encapsulate 160, which may be in liquid form, may then fill the remaining volume of the recessed portion 117 up to the level of the sidewalls 118. In this way, no air remains in the recessed portion 117. After the encapsulate 160 is poured or otherwise introduced into the recessed portion 117, the encapsulate 160 may be cured to form a solid material. The encapsulate 160 may be selected so as to be transparent at the wavelengths emitted by the LEDs 130. The term “transparent” is intended to describe the property wherein at least 80% of the light energy emitted by the LEDs 130 passes through the encapsulate 160. Further, the encapsulate 160 may be selected such that the material does not outgas in a vacuum environment. In certain embodiments, the encapsulate 160 may be silicone, or silicone oil. In other embodiments, other clear epoxy materials, such as polyurethane, may be used. As described above, a sealed enclosure may have differential pressure between the interior and the vacuum chamber. By removing the air from the recessed portion 117 through the use of an encapsulate 160, this pressure differential may be eliminated. The encapsulate 160 may also serve as a mechanical support for the window 140. In certain embodiments, the encapsulate 160 may be used to hold the window 140 in place, such that fasteners are not needed.

In embodiments where the LED substrate heater is not disposed in vacuum conditions, the encapsulate 160 may or may not be employed. For example, in environments that operate at or near atmospheric pressure, no pressure differential exists between the interior of the recessed portion 117 and the exterior. Thus, the encapsulate 160 may not be used in these embodiments.

A sealing gasket 150 may be disposed between the window 140 and the sidewalls 118. In embodiments where the sidewalls 118 are separate from the base 110, a sealing gasket may also be disposed between the sidewalls 118 and the base 110. The sealing gasket 150 also prevents the outgassing of the encapsulate 160 from the recessed portion 117 to the vacuum chamber. Additionally, the sealing gasket 150 may prevent migration of other materials from the LEDs 130 to the vacuum chamber. The sealing gasket 150 may be made from Viton® or any suitable material. These materials may be selected due to their compatibility with vacuum conditions.

In certain embodiments, the window 140 may be coated on one or both surfaces with an optical coating 141. This optical coating 141 may be used to reflect wavelengths, such as infrared radiation from the substrate, back toward the substrate. Additionally, as described above, the top surface of the recessed portion 117 may be polished to also reflect light and other radiation back toward the substrate. The optical coating 141 on the window 140 and polished surface may serve to keep the LEDs 130 cooler while also helping reduce wafer heat loss.

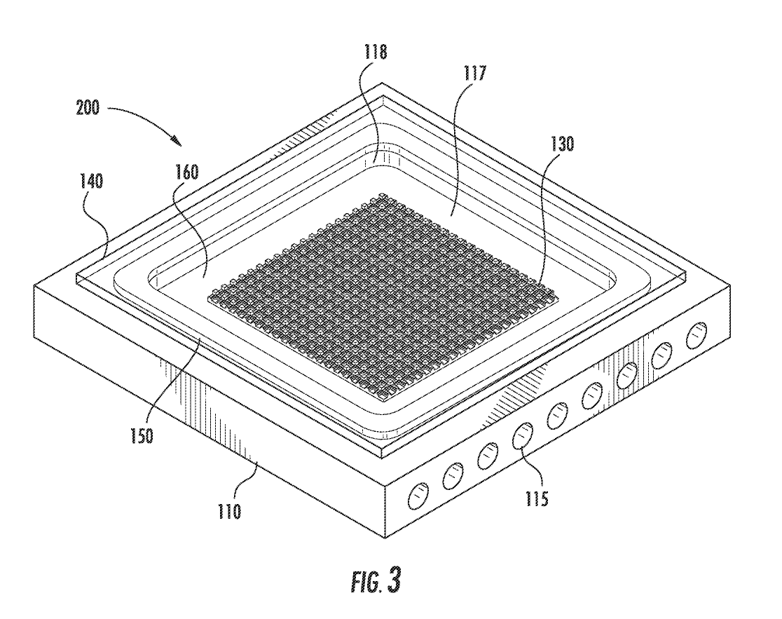

While FIG. 1 shows a printed circuit board 120 disposed in the recessed portion 117, other embodiments are also within the scope of the disclosure. For example, FIG. 3 shows a perspective view of a second embodiment of a LED substrate heater 200. Components that are shared between these two embodiments have been given identical reference designators.

In this embodiment, the printed circuit board is replaced by a plurality of thick film insulating and conductive traces, which are disposed directly on the top surface of the recessed portion 117. Like the previous embodiment, the LED substrate heater 200 comprises a base 110 which may have conduits 115. The base 110 has a recessed portion 117 surrounded by sidewalls 118. As described above, the sidewalls 118 may be integral with the base 110, or may be separate components. A window 140 is disposed on the sidewalls 118. A sealing gasket 150 may be disposed between the window 140 and the sidewalls 118. An encapsulate 160 may be disposed in the recessed portion 117 created by the sidewalls 118.

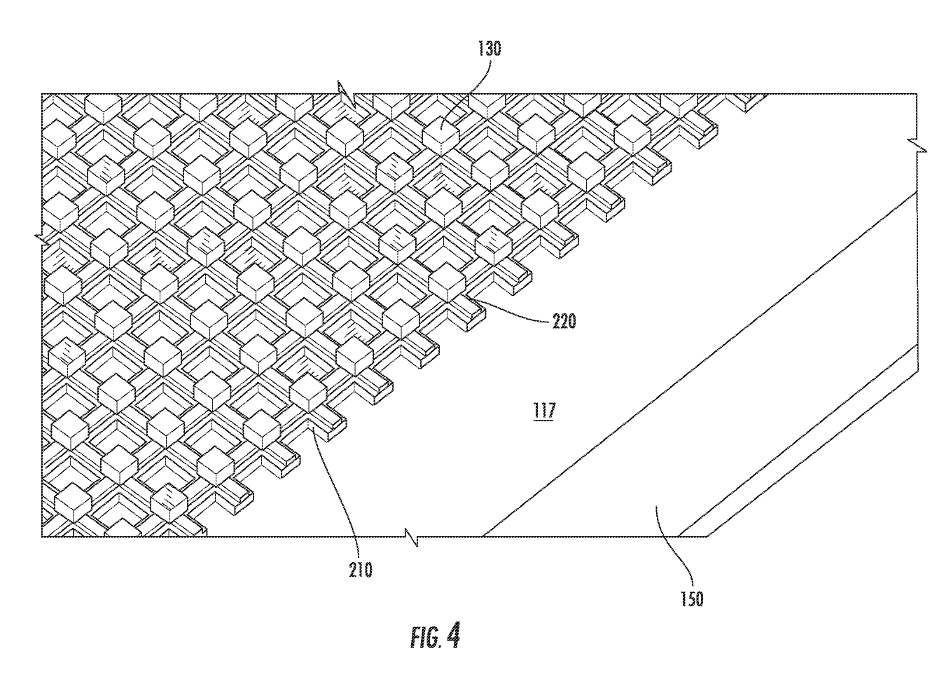

FIG. 4 shows an expanded view of the recessed portion 117 of the embodiment of FIG. 3. Disposed directly on the upper surface of the recessed portion 117 is a plurality of insulating traces 210. The insulating traces 210 may cover the entirety of the upper surface of the recessed portion 117. In other embodiments, such as that shown in FIG. 4, the insulating traces 210 are disposed in a pattern, such that portions of the upper surface of the recessed portion 117 remain exposed. Disposed on the insulating traces 210 is a plurality of conductive traces 220. The conductive traces 220 are used to carry current to the LEDs 130. The insulating traces 210 are used to electrically isolate the conductive traces 220 from the recessed portion 117. The conductive traces 220 are electrically connected to a power source (not shown) and to the LEDs 130.

Unlike the previous embodiment, the insulating traces 210 are applied directly to the recessed portion 117. Therefore, fasteners are not employed. Further, since the insulating traces 210 is disposed directly on the upper surface of the recessed portion 117 of the base 110, thermal conductivity may be much improved. In other words, the embodiment of FIG. 4 may be more effective in pulling heat from the LEDs 130 and sinking that heat to the base 110. In certain embodiments, a thick film material system, such as that available from Heraeus Celcion®, may be used.

In both embodiments, the LEDs 130 are part of an electrical circuit that is disposed in the recessed portion 117 of the base 110. Electrical connections are made between the LEDs 130 and a power supply. As described above, in certain embodiments, the electrical circuit is fabricated on a printed circuit board, or a metal core printed circuit board. In other embodiments, the electrical circuit is fabricated using thick films. These films are used to create insulating traces and conductive traces. Of course, the electrical circuit may be fabricated in other ways as well.

Further, in certain embodiments, reflective materials or reflective surfaces may be used to maximize the transfer of light energy from the LEDs 130 to the substrate. This may maximize the heating of the substrate, while also keeping the LEDs 130 at a lower temperature. As described above, in certain embodiments, an optical coating 141 may be disposed on the window 140. This optical coating 141 serves to reflect infrared radiation back toward the substrate. In certain embodiments, the top surface of the recessed portion 117 may be polished to increase its reflectivity. In certain embodiments, reflective material may be disposed on top of the electrical circuit, such as between the LEDs 130. In the case of a printed circuit board 120, a reflective material may be disposed on the top surface of the printed circuit board. In the case of thick films, the reflective material may be disposed on top of these thick films. This reflective material, which may be a solder mask, also reflects light back toward the substrate.

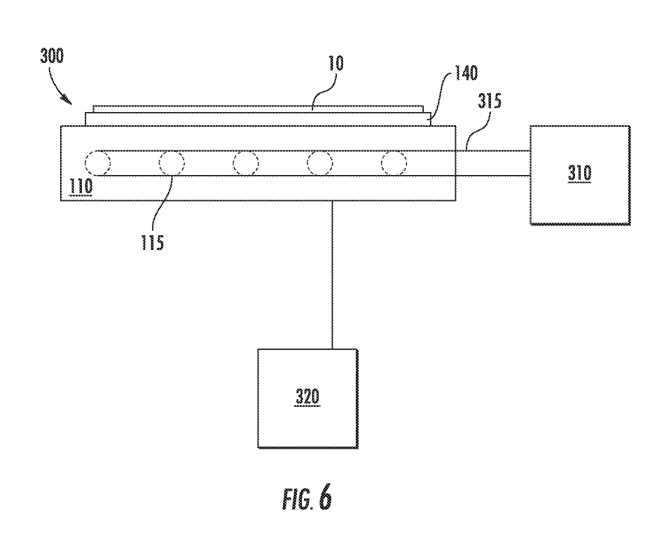

FIG. 6 shows a LED substrate heater 300 as deployed in a chamber. The LED substrate heater 300 may be either of the embodiments described herein. The LED substrate heater 300 is in fluid communication with a fluid source 310. The fluid source 310 may be a liquid container having a pump to force the liquid through the piping 315 and into the conduits 115 in the base 110 of the LED substrate heater 300. In other embodiments, the fluid source 310 may be a source of cooled gas. Additionally, the LEDs in the LED substrate heater 300 are electrically connected to a power supply 320. In certain embodiments, the power connections to the LEDs exit through a small bore in the base 110.

In operation, the LED substrate heaters described herein may be disposed on a horizontal surface, such that the substrate 10 may be disposed on the window 140 of the LED substrate heater 300. In this embodiment, the LED substrate heater 300 heats the substrate 10 from below.

In other embodiments (not shown), the LED substrate heaters 300 may be disposed at an elevated position and oriented such that the window 140 faces downward. In this embodiment, the LED substrate heater 300 heats the substrate from above. In yet another embodiment, two LED substrate heaters 300 may be arranged such that the substrate 10 is disposed on the window 140 of a first LED substrate heater, while a second LED substrate heater is oriented to emit light downward toward the substrate 10. In this way, the substrate 10 may be heated from both above and below simultaneously.

The embodiments described above in the present application may have many advantages. First, as described above, the LED substrate heater may be less than 0.5 inches thick. Due to the compact size of the LED substrate heater, these heaters may be disposed within the chamber in spaces that previously were not available. Secondly, the LED substrate heater utilizes LEDs, which are far more efficient at heating substrates than conventional heat lamps. Therefore, less power is used to warm the substrates as compared to the prior heating systems. Further, LEDs provide all energy at a specific wavelength, where traditional heating systems are broader in spectrum. This allows for selection of a wavelength that couples efficiently to the substrate being heated. Further, all the input energy is at that target wavelength. This also allows for adding reflective surfaces that reflect that targeted wavelength, such as a solder mask over the printed circuit board to reflect light back toward the substrate. Third, the design of the LED substrate heater allows the heater to be used to heat the substrate from below, when the substrate is disposed on the window, or above. Finally, LEDs are far more reliable, having a life of roughly five years, compared to less than one year for traditional heating lamps.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

What is claimed is:

1. An apparatus comprising:
a sealed enclosure containing an electrical circuit comprising a plurality of LEDs, wherein a top surface of the sealed enclosure comprises a window that is transparent at a wavelength emitted by the plurality of LEDs.

2. The apparatus of claim 1, wherein the sealed enclosure is filled with an encapsulate to remove air.

3. The apparatus of claim 1, wherein the plurality of LEDs emits light at a wavelength between about 0.4 and 1.0 μm.

4. The apparatus of claim 1, wherein the plurality of LEDs is arranged as a pattern of concentric circles, where concentric circles disposed further from a center of the pattern have more LEDs than concentric circles disposed closer to the center of the pattern.

5. The apparatus of claim 1, further comprising an optical coating on the window to reflect infrared radiation toward a substrate.

6. An LED substrate heater, comprising:
a base having a recessed portion surrounded by sidewalls;
an electrical circuit, comprising a plurality of LEDs, disposed in the recessed portion; and
a window disposed on top of the sidewalls and covering the recessed portion, forming a sealed enclosure in which the electrical circuit is disposed, wherein the window is transparent at a wavelength emitted by the plurality of LEDs.

7. The LED substrate heater of claim 6, further comprising:
a conduit passing through a length of the base, configured to allow a fluid to pass therethrough to remove heat from the base.

8. The LED substrate heater of claim 6, wherein the electrical circuit comprises a printed circuit board, and the printed circuit board is in thermal communication with an upper surface of the recessed portion.

9. The LED substrate heater of claim 8, wherein the printed circuit board comprises a metal core printed circuit board.

10. The LED substrate heater of claim 6, wherein the electrical circuit comprising insulating traces and conductive traces, wherein the insulating traces are applied directly to an upper surface of the recessed portion, the conductive traces are applied on top of the insulating traces, and the conductive traces are in electrical communication with the plurality of LEDs.

11. The LED substrate heater of claim 6, further comprising an encapsulate which fills a remaining volume of the recessed portion, wherein the encapsulate is transparent at the wavelength emitted by the plurality of LEDs.

12. The LED substrate heater of claim 11, wherein the encapsulate comprises silicone.

13. The LED substrate heater of claim 6, wherein the plurality of LEDs are arranged as a pattern of concentric circles, where concentric circles disposed further from a center of the pattern have more LEDs than concentric circles disposed closer to the center of the pattern.

14. The LED substrate heater of claim 13, wherein the pattern comprises a plurality of bands, where each concentric circle disposed in a particular band has a same number of LEDs.

15. The LED substrate heater of claim 14, wherein the pattern comprises 5 bands.

16. The LED substrate heater of claim 6, further comprising an optical coating on the window to reflect infrared radiation toward a substrate.

17. The LED substrate heater of claim 6, further comprising a reflective material disposed on the electrical circuit to reflect light from the plurality of LEDs.

18. An LED substrate heater, comprising:
a base having a recessed portion surrounded by sidewalls;
an electrical circuit, comprising a plurality of LEDs arranged as a pattern of concentric circles, disposed in the recessed portion;
an encapsulate disposed in the recessed portion; and
a window disposed on top of the sidewalls, covering the recessed portion and in contact with the encapsulate, forming a sealed enclosure in which the electrical circuit is disposed, wherein the window and the encapsulate are transparent at a wavelength emitted by the plurality of LEDs.

19. The LED substrate heater of claim 18, wherein the pattern comprises a plurality of bands, where all concentric circles disposed in a particular band have a same number of LEDs.

20. The LED substrate heater of claim 19, wherein the pattern comprises 5 bands.
